(19) United States
(12) Patent Application Publication
(10) Pub. No.: US 2023/0170309 A1
(43) Pub. Date: Jun. 1, 2023

(54) SEMICONDUCTOR PACKAGE INCLUDING FIDUCIAL MARK

(71) Applicant: SAMSUNGELECTRONICSCO.,LTD., Suwon-si (KR)

(72) Inventors: JIYEON LEE, Asan-si (KR); Hyejin KIM, Suwon-si (KR)

(73) Assignee: SAMSUNGELECTRONICSCO.,LTD., Suwon (KR)

(21) Appl. No.: 18/052,416

(22) Filed: Nov. 3, 2022

(30) Foreign Application Priority Data
Nov. 26, 2021 (KR) 10-2021-0166049

(51) Int. Cl. H01L 23/544; H01L 25/10; H01L 23/31

(52) U.S. Cl. CPC H01L 23/544; H01L 25/105; H01L 23/3128; H01L 2223/54426; H01L 2224/16227; H01L 24/16

(57) ABSTRACT

A semiconductor package includes at least one first semiconductor chip on a substrate. The substrate includes a body layer having top and bottom surfaces, first fiducial marks on the top surface of the body layer, and a first protection layer on at least edges of the first fiducial marks, the first protection layer having first openings that expose top surfaces of the first fiducial marks. The first fiducial marks include first mark exposure portions that are each exposed without being covered by the first protection layer. Each of the first mark exposure portions includes a first circular segment and at least four first protruding segments outwardly protruding from the first circular segment. Angles between sidewalls of adjacent first protruding segments may be identical with each other. Lateral lengths of the first protruding segments that outwardly protrude from the first circular segment may be identical with each other.

### CROSS-REFERENCE TO RELATED APPLICATION

This application is based on and claims priority from Korean Patent Application No. 10-2021-0166049 filed on Nov. 26, 2021 in the Korean Intellectual Property Office, the disclosure of which is incorporated herein in its entirety by reference.

### BACKGROUND

The disclosure relates to a semiconductor package, and more particularly, to a semiconductor package including a fiducial mark.

A semiconductor package is provided to implement an integrated circuit chip to qualify for use in electronic devices. A semiconductor package is typically configured such that a semiconductor die may be mounted on a printed circuit board (PCB) and bonding wires or bumps may be used to electrically connect the semiconductor die to the printed circuit board. With the development of the electronic industry, many studies have been conducted to improve reliability and durability of semiconductor packages.

### SUMMARY

Some embodiments of the disclosure provide a semiconductor package with increased reliability.

The object of the disclosure is not limited to the mentioned above, and other objects which have not been mentioned above will be clearly understood to those skilled in the art from the following description.

In accordance with an aspect of the disclosure, a semiconductor package includes a substrate; and at least one first semiconductor chip on the substrate, wherein the substrate includes a body layer that has a top surface and a bottom surface; at least two first fiducial marks on the top surface of the body layer; and a first protection layer on at least edges of each of the at least two first fiducial marks, the first protection layer having first openings that each expose a respective top surface of the at least two first fiducial marks, wherein each of the at least two first fiducial marks includes at least one first mark exposure portion that is exposed without being covered by the first protection layer, wherein, when viewed in plan, each of the at least one first mark exposure portion includes a first circular segment and at least four first protruding segments that outwardly protrude from the first circular segment, wherein angles between sidewalls of adjacent ones of the at least four first protruding segments are identical with each other, and wherein a lateral length of each of the at least four first protruding segments that outwardly protrude from the first circular segment is identical to the lateral length of each other of the at least four protruding segments.

In accordance with an aspect of the disclosure, a semiconductor package includes a substrate; and at least one first semiconductor chip on the substrate, wherein the substrate includes a body layer that has a top surface and a bottom surface; at least two first fiducial marks on the top surface of the body layer; and a first protection layer on at least edges of each of the at least two first fiducial marks, the first protection layer having first openings that each expose a respective top surface of the at least two first fiducial marks, wherein each of the at least two first fiducial marks includes at least one first mark exposure portion that is exposed without being covered by the first protection layer, wherein, when viewed in plan, each of the at least one first mark exposure portion includes a first circular segment and at least one cavity inside the first circular segment, and wherein the at least one cavity of each of the at least one first mark exposure portion has a radially symmetric shape.

In accordance with an aspect of the disclosure, a semiconductor package includes a substrate; at least one first semiconductor chip on the substrate; and a mold layer on the first semiconductor chip and the substrate, wherein the substrate includes a body layer that has a top surface and a bottom surface; at least two first fiducial marks on the top surface of the body layer; and a first protection layer on at least edges of each of the at least two first fiducial marks, the first protection layer having first openings that each expose a respective top surface of the at least two first fiducial marks, wherein each of the at least two first fiducial marks includes at least one first mark exposure portion that is exposed without being covered by the first protection layer, wherein, when viewed in plan, each of the at least one first mark exposure portion includes a first circular segment and four first protruding segments that outwardly protrude from the first circular segment, wherein each of angles between sidewalls of adjacent ones of the four first protruding segments is about 90°, wherein a lateral length of each of the four first protruding segments that outwardly protrude from the first circular segment is identical to the lateral length of each other of the four first protruding segments, wherein the first circular segment of each of the at least one first mark exposure portion has a diameter of about 100 μm to about 200 μm, and wherein each of the at least one first mark exposure portion has a width of about 300 μm to about 400 μm.

In accordance with an aspect of the disclosure, a semiconductor package includes a substrate; and at least one semiconductor chip on the substrate, wherein the substrate includes a body layer that has a top surface and a bottom surface; at least two fiducial marks on the top surface of the body layer; an upper conductive pad on the top surface of the body layer; and a protection layer on at least edges of each of the at least two fiducial marks, the protection layer having openings that each expose a respective top surface of the at least two fiducial marks, and wherein the at least two fiducial marks and the upper conductive pad comprise a same conductive material and are provided at a same level.

### BRIEF DESCRIPTION OF DRAWINGS

FIG. 1 illustrates a plan view showing a semiconductor package according to embodiments.

FIG. 2A illustrates a cross-sectional view taken along line A-A′ of FIG. 1, showing a semiconductor package according to embodiments.

FIG. 2B illustrates a cross-sectional view showing a method of fabricating the semiconductor package of FIG. 2A.

FIG. 3A illustrates an enlarged view showing section P1 of FIG. 1.

FIG. 3B illustrates a cross-sectional view taken along line B-B′ of FIG. 3A.

FIG. 3C illustrates a plan view showing recognition of a mark exposure portion depicted in FIG. 3A.

FIG. 4A illustrates an enclosed plan view showing a fiducial mark according to embodiments.

FIG. 4B illustrates a cross-sectional view taken along line B-B′ of FIG. 4A.

FIG. 4C illustrates a plan view showing recognition of a mark exposure portion of FIG. 4A.

FIGS. 5A to 5H illustrate plan views showing shapes of mark exposure portions in fiducial marks according to embodiments.

FIGS. 6 to 10 illustrate plan views showing semiconductor packages according to embodiments.

FIGS. 11 and 12 illustrate cross-sectional views showing semiconductor packages according to some embodiments of the present inventive concepts.

### DETAIL DESCRIPTION OF EMBODIMENTS

Some embodiments will now be described in detail with reference to the accompanying drawings to aid in clearly explaining the disclosure. In this description, such terms as “first” and “second” may be used to simply distinguish identical or similar components from each other, and the sequence of such terms may be changed in accordance with the order of mention.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present. Like numerals refer to like elements throughout.

Spatially relative terms, such as “over,” “above,” “on,” “upper,” “below,” “under,” “beneath,” “lower,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

For the sake of brevity, conventional elements to semiconductor devices may or may not be described in detail herein for brevity purposes.

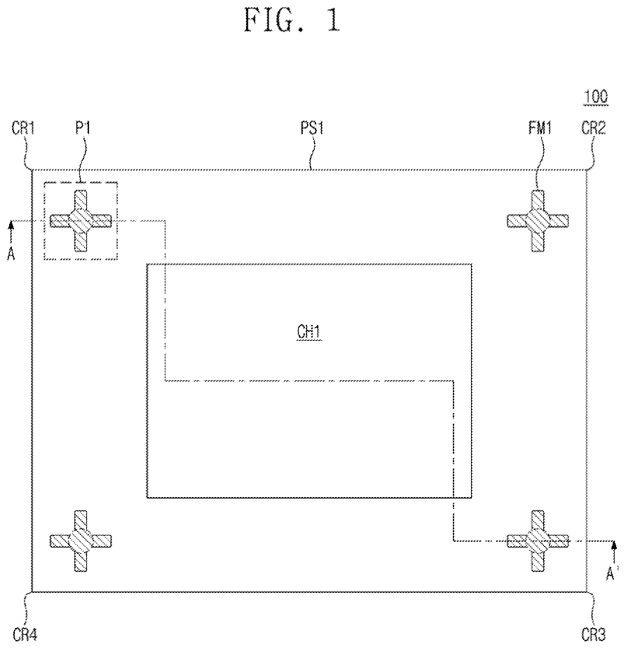

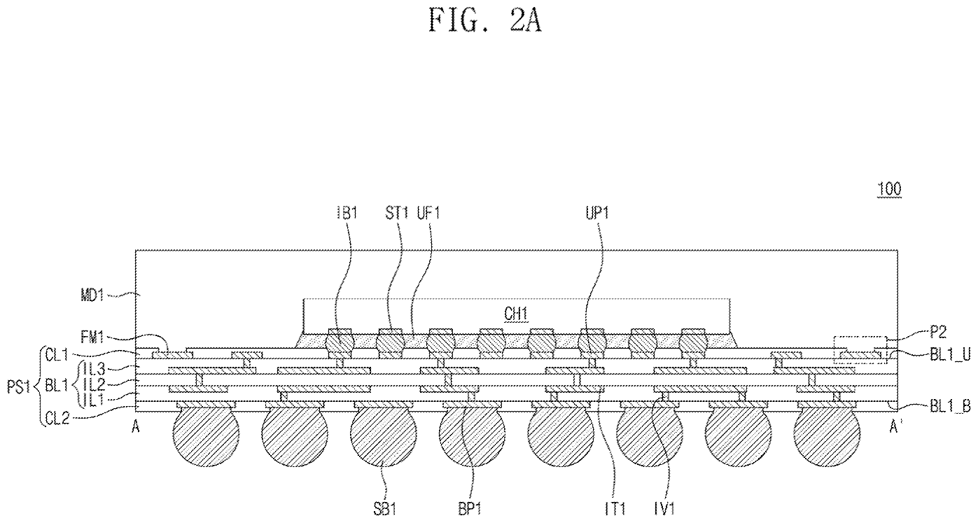

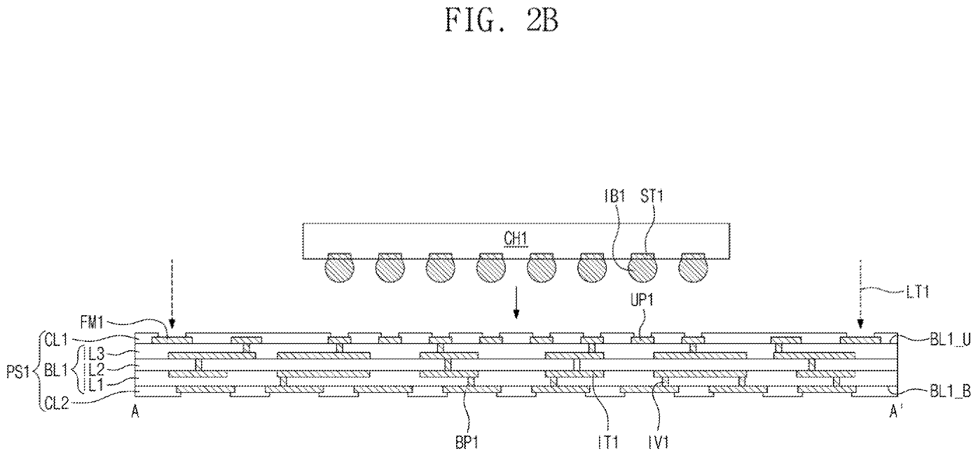

FIG. 1 illustrates a plan view showing a semiconductor package according to some embodiments of the disclosure. FIG. 2A illustrates a cross-sectional view taken along line A-A′ of FIG. 1, showing a semiconductor package according to some embodiments of the disclosure.

Referring to FIGS. 1 and 2A, a semiconductor package 100 according to some embodiments may include a first substrate PS1, a first semiconductor device CH1 mounted on the first substrate PS1, and a first mold layer MD1 that covers a sidewall of the first semiconductor device CH1. Although a single first semiconductor device CH1 is disclosed in the present embodiment, a plurality of first semiconductor chips CH1 may be provided laterally spaced apart from each other or vertically stacked on each other in sequence. The first semiconductor device CH1 may be one selected from an image sensor chip such as a complementary metal oxide semiconductor (CMOS) image sensor (CIS), a microelectromechanical system (MEMS) device chip, an application specific integrated circuit (ASIC) chip, and a memory device chip such as a flash memory, a dynamic random access memory (DRAM), a static random access memory (SRAM), an electrically erasable programmable read-only memory (EEPROM), a phase change random access memory (PRAM), a magneto-resistive random access memory (MRAM), a resistive random access memory (ReRAM), a high bandwidth memory (HBM), and a hybrid memory cubic (HMC).

The first mold layer MD1 may include a dielectric resin, such as an epoxy molding compound (EMC). The first mold layer MD1 may further include fillers, and the fillers may be dispersed in the dielectric resin.

The first substrate PS1 may be, for example, a multi-layered printed circuit board. The first substrate PS1 may include a first body layer BL1, a first protection layer CL1 that covers a top surface BL1_U of the first body layer BL1, and a second protection layer CL2 that covers a bottom surface BL1_B of the first body layer BL1. The first substrate PS1 may include first, second, and third dielectric layers IL1, IL2, and IL3 that are sequentially stacked. The first, second, and third dielectric layers IL1, IL2, and IL3 may each include one or more of a thermosetting resin such as epoxy resin, a thermoplastic resin such as polyimide, a resin in which a thermosetting or thermoplastic resin is impregnated with a reinforcement such as glass fiber and/or inorganic filler (which impregnated resin includes a prepreg or a fire resist-4 (FR4)), and a photosensitive resin, but the disclosure is not limited thereto. The first and second protection layers CL1 and CL2 may each be a photo-solder resist (PSR) layer.

The first body layer BL1 may be provided on its top surface BL1_U with first upper conductive pads UP1 and first fiducial marks FM1. The first upper conductive pads UP1 and the first fiducial marks FM1 may include the same conductive material and may be located at the same level as each other. For example, the first upper conductive pads UP1 and the first fiducial marks FM1 may include metal, such as copper, aluminum, nickel, or gold.

When viewed in plan, the first substrate PS1 may have first to fourth corners CR1 to CR4 that are disposed along a clockwise direction. Four first fiducial marks FM1 may be correspondingly disposed adjacent to the first to fourth corners CR1 to CR4.

A plurality of first lower conductive pads BP1 may be disposed on the bottom surface BL1_B of the first body layer BL1. The first lower conductive pads BP1 may include metal, such as copper, aluminum, nickel, or gold.

First internal lines IT1 and first vias IV1 that connect the first internal lines IT1 to each other may be provided in the first substrate PS1. The first vias IV1 may correspondingly penetrate the first, second, and third dielectric layers Ill, IL2, and IL3. The first lower conductive pads BP1 may be electrically connected to the first upper conductive pads UP1 through the first internal lines IT1 and the first vias IV1.

The first substrate PS1 may be provided thereunder with a plurality of first external connection terminals SB1 that are correspondingly bonded to the first lower conductive pads BP1. The first external connection terminals SB1 may each include at least one selected from solder balls, conductive bumps, and conductive pillars. The solder ball may include Sn or SnAg. The conductive bump or the conductive pillar may include copper.

A plurality of first chip terminals ST1 may be disposed on a bottom surface of the first semiconductor device CH1. A plurality of first internal connection members IB1 may be interposed between the first chip terminals ST1 and the first upper conductive pads UP1, thereby connecting the first chip terminals ST1 to the first upper conductive pads UP1. The first internal connection members IB1 may each include at least one selected from solder balls, conductive bumps, and conductive pillars. The solder ball may include Sn or SnAg. The conductive bump or the conductive pillar may include copper.

A first under-fill layer UF1 may be interposed between the first semiconductor device CH1 and the first substrate PS1. The first under-fill layer UF1 may include a thermo-curable resin or a photo-curable resin. In addition, the first under-fill layer UF1 may further include organic fillers or inorganic fillers.

FIG. 2B illustrates a cross-sectional view showing a method of fabricating the semiconductor package of FIG. 2A.

Referring to FIG. 2B, light LT1 may be used to recognize the first fiducial marks FM1 on the first substrate PS1, and then to find a location on which the first semiconductor device CH1 is intended to be mounded. Afterwards, the first semiconductor device CH1 may be placed at the right position, and heat may be applied to reflow solder layers of the first internal connection members IB1, with the result that the first internal connection members IB1 may be bonded to the first upper conductive pads UP1. Thereafter, the first under-fill layer UF1 and the first mold layer MD1 may be formed, and the first external connection terminals SB1 may be bonded to the first lower conductive pads BP1.

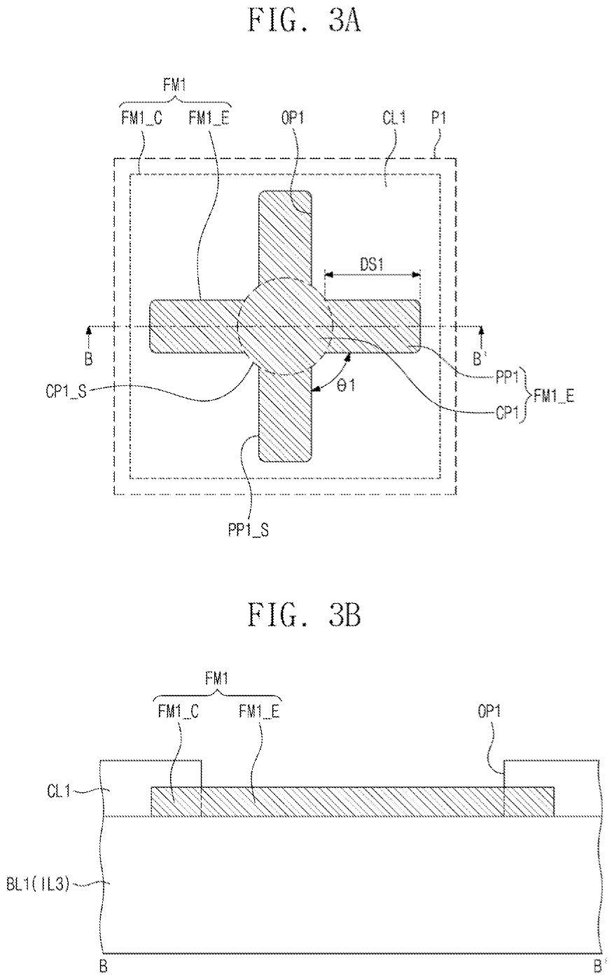

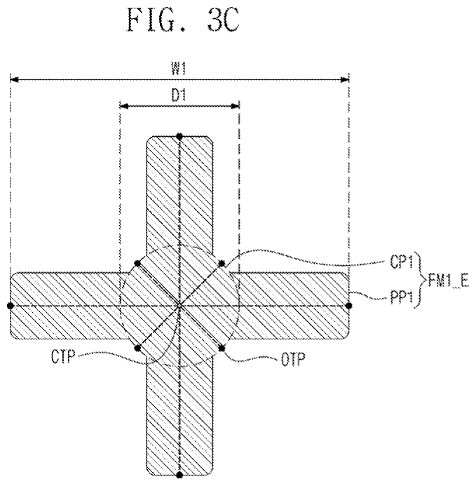

FIG. 3A illustrates an enlarged view showing section P1 of FIG. 1. FIG. 3B illustrates a cross-sectional view taken along line B-B′ of FIG. 3A. FIG. 3C illustrates a plan view showing recognition of a mark exposure portion depicted in FIG. 3A. FIG. 3B may correspond to a drawing that shows section P2 of FIG. 2A.

Referring to FIGS. 3A to 3C, the first fiducial mark FM1 may include a first mark coverage portion FM1_C that is covered with the first protection layer CL1, and may also include a first mark exposure portion FM1_E that is exposed without being covered with the first protection layer CL1. The first protection layer CL1 may have a first opening OP1 that exposes the first mark exposure portion FM1_E. In an embodiment, the first mark coverage portion FM1_C may be positioned on an edge or edges of the first fiducial mark FM1. For example, the first mark coverage portion FM1_C may surround the first fiducial mark FM1. When the first fiducial marks FM1 are recognized with the light LT1 as shown in FIG. 2B, the first mark coverage portion FM1_C may not be recognized, and only the first mark exposure portion FM1_E may be recognized.

When viewed in plan as shown in FIG. 3A, the first mark exposure portion FM1_E may have a first circular segment CP1 positioned on a center thereof, and may also have first protruding segments PP1 that outwardly protrude from a circumference CP1_S of the first circular segment CP1. There may be a constant angle between sidewalls PP1_S of the first protruding segments PP1 that are adjacent to each other. In an embodiment, the number of the first protruding segments PP1 may be four, and an angle θ1 of about 90° may be provided between the sidewalls PP1_S of adjacent first protruding segments PP1. The same length DS1 may be provided to the sidewalls PP 1_S of the first protruding segments PP1 that outwardly protrude from the circumference CP1_S of the first circular segment CP1. The length DS1 may range, for example, from about 10 μm to about 200 μm.

When viewed in plan as shown in FIG. 3C, the first circular segment CP1 may have a first diameter D1. The first mark exposure portion FM1_E may have a first width W1 from an end of one first protruding segment PP1 to an end of an opposite one of the first protruding segments PP1. The first diameter D1 may be in a range, for example, from about 100 μm to about 200 μm. The first width W1 may be in a range, for example, from about 300 μm to about 400 μm. The first diameter D1 may be in a range from about 160 μm to about 180 μm. The first width W1 may be in a range from about 370 μm to about 390 μm.

As illustrated in FIG. 3C, when the first fiducial marks FM1 are recognized with the light LT1, it may be possible to recognize circumferential points OTP of the first mark exposure portion FM1_E and to find a central point CTP between symmetrically opposed ones of the circumferential points OTP. Therefore, positions (e.g., the central points CTP) of each of the first fiducial marks FM1 may be accurately perceived to determine a mount location of the first semiconductor device CH1. In the disclosure, the first mark exposure portion FM1_E of the first fiducial mark FM1 may have a radially symmetric shape, and thus it may be easy to exactly find the central point CTP of the first mark exposure portion FM1_E.

Moreover, in the disclosure, the first mark exposure portion FM1_E may have a shape in which the first circular segment CP1 is combined with angularly formed segments (e.g., the first protruding segments PP1). The circumference CP1_S of the first circular segment CP1 may be easily and constantly implemented almost without damage or variation in etching, development, and/or cleaning processes. Therefore, it may be easy to accurately recognize the circumferential points OTP on the circumference CP1_S of the first circular segment CP1. Hence, it may be easy to exactly find the central point CTP of the first mark exposure portion FM1_E. The first protruding segments PP1, which are angularly shaped, may be favorably used to identify directions. Accordingly, the first semiconductor device CH1 may be mounted on an exact location, and process defects may not occur to increase a manufacturing yield.

When the first mark exposure portion FM1_E has a rectangular or asymmetric shape when viewed in plan, damage or variation may be produced in etching, development, and/or cleaning processes and thus circumferential lines may be partially rounded or damaged. In this case, the circumferential points OTP may be difficult to exactly recognize, and the central point CTP of the first mark exposure portion FM1_E may be hard to accurately find. For this reason, the first semiconductor device CH1 may be mounted on a wrong location, and process defects may be produced to decrease a manufacturing yield.

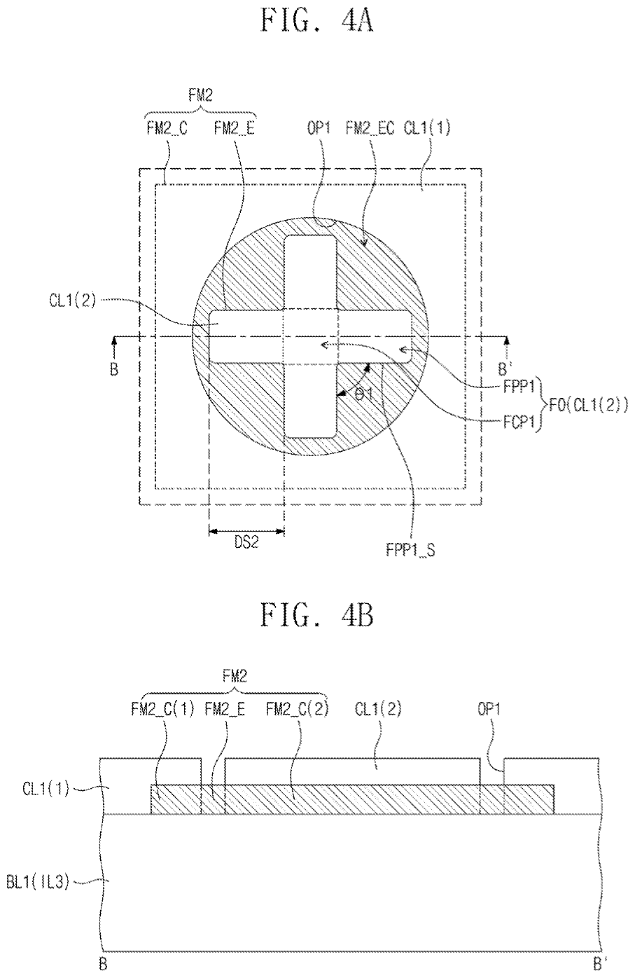

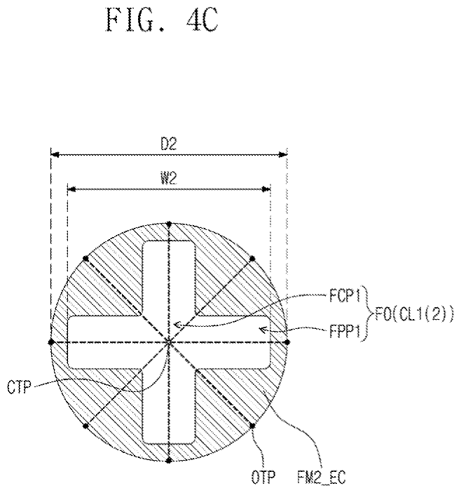

FIG. 4A illustrates an enclosed plan view showing a fiducial mark according to some embodiments. FIG. 4B illustrates a cross-sectional view taken along line B-B′ of FIG. 4A. FIG. 4C illustrates a plan view showing recognition of a mark exposure portion depicted in FIG. 4A.

Referring to FIGS. 4A to 4C, a second fiducial mark FM2 according to an embodiment may include a second-first mark coverage portion FM2_C(1) that is covered with a first-first protection layer CL1(1), a second-second mark coverage portion FM2_C(2) that is covered with a first-second protection layer CL1(2), and a second mark exposure portion FM2_E that is exposed without being covered with a first protection layer CL1.

The first protection layer CL1 may have a first opening OP1 that exposes the second mark exposure portion FM2_E. In an embodiment, the first-first protection layer CL1(1) may be positioned on an edge of the second fiducial mark FM2. The first-second protection layer CL1(2) may be positioned on a center of the second fiducial mark FM2. When the second fiducial mark FM2 is recognized with the light LT1 as shown in FIG. 2B, the second-first mark coverage portion FM2_C(1) and the second-second mark coverage portion FM2_C(2) may not be recognized, and only the second mark exposure portion FM2_E may be recognized. A second mark coverage portion FM2_C may include the second-first mark coverage portion FM2_C(1) and the second-second mark coverage portion FM2_C(2).

When viewed in plan as shown in FIG. 4A, the second mark exposure portion FM2_E may be implemented such that a cavity FO is formed inside a circular segment FM2_EC. The cavity FO may correspond to the first-second protection layer CL1(2). The cavity FO may have a cross shape when viewed in plan. For example, the cavity FO may have a cavity central segment FCP1 that is positioned on a center thereof, and may also have first cavity protruding segments FPP1 that outwardly protrude from the cavity central segment FCP1. There may be a constant angle between sidewalls FPP1_S of the first cavity protruding segments FPP1 that are adjacent to each other. In an embodiment, the number of the first cavity protruding segments FPP1 may be four, and an angle θ1 of about 90° may be provided between the sidewalls FPP1_S of adjacent first cavity protruding segments FPP1. The same length DS2 may be provided to the sidewalls FPP1_S of the first cavity protruding segments FPP1 that outwardly protrude from the cavity central segment FCP1. The length DS2 may be in a range, for example, from about 60 μm to about 100 μm.

When viewed in plan as shown in FIG. 4C, as regards the second mark exposure portion FM2_E, the circular segment FM2_EC may have a second diameter D2. The second diameter D2 may be in a range, for example, from about 300 μm to about 400 μm. The cavity FO, or the first-second protection layer CL1(2), may have a second width W2 of about 200 μm to about 280 μm from an end of one of the first cavity protruding segments FPP1 to an end of an opposite one of the first cavity protruding segments FPP1.

When the second fiducial marks FM2 are recognized with the light LT1 as shown in FIG. 2B, it may be possible to recognize circumferential points OTP on the circular segment FM2_EC of the second mark exposure portion FM2_E and to find a central point CTP between symmetrically opposed ones of the circumferential points OTP. Therefore, positions (e.g., the central points CTP) of the second fiducial marks FM2 may be accurately perceived to determine a mount location of the first semiconductor device CH1. In the disclosure, the second mark exposure portion FM2_E of the second fiducial mark FM2 may have a radially symmetric shape, and thus it may be easy to exactly find the central point CTP of the second mark exposure portion FM2_E.

Moreover, in the disclosure, it may be easy to accurately recognize the circumferential points OTP on a circumference of the circular segment FM2_EC of the second mark exposure portion FM2_E. Hence, it may be easy to exactly find the central point CTP of the second mark exposure portion FM2_E. Accordingly, the first semiconductor device CH1 may be mounted on an exact location, and process defects may not occur to increase a manufacturing yield.

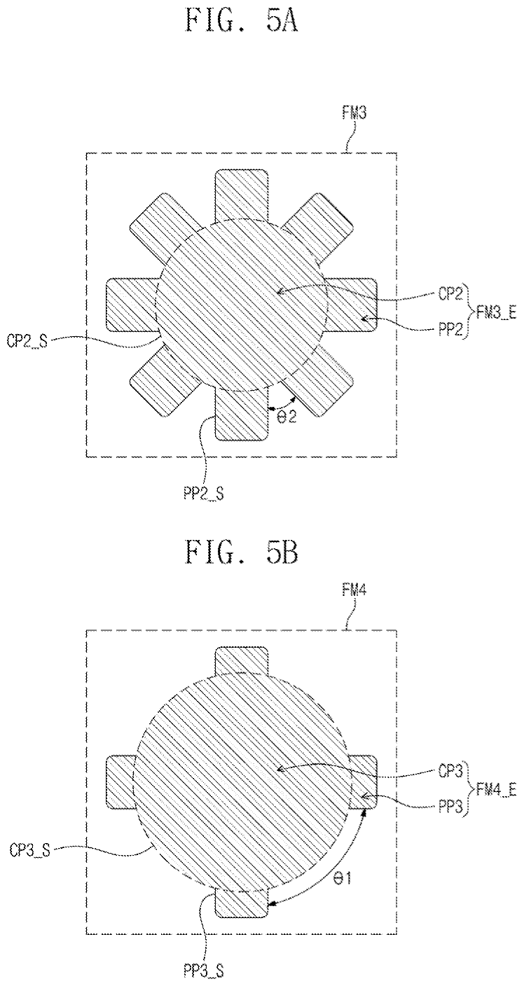

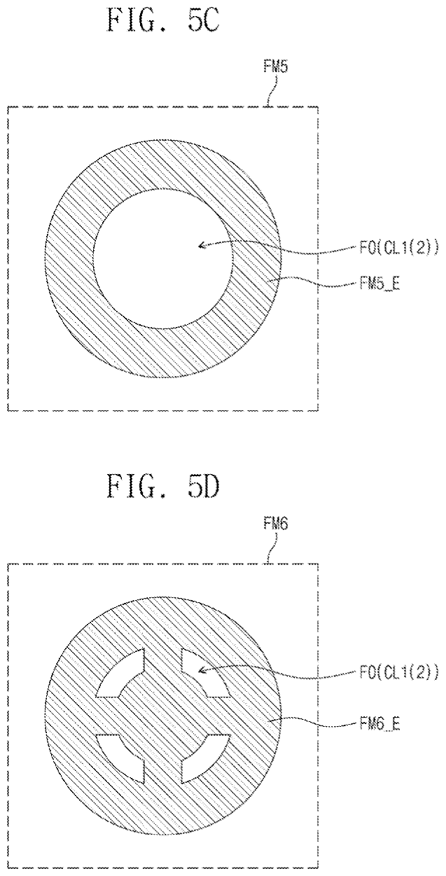

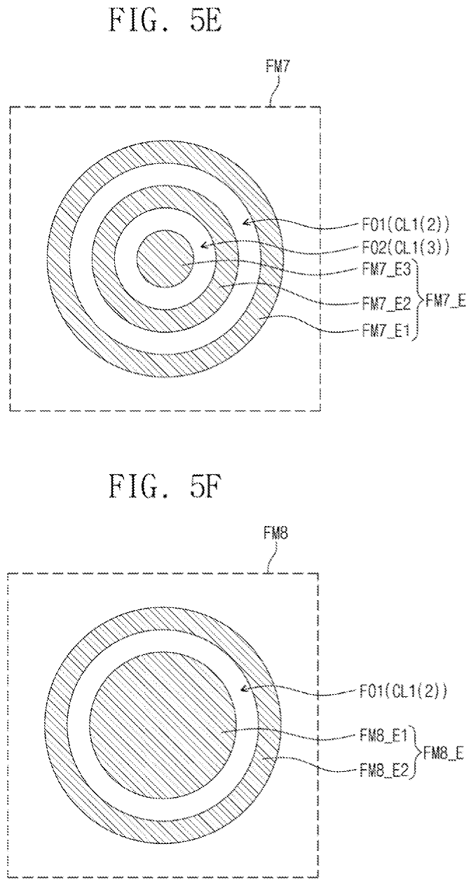

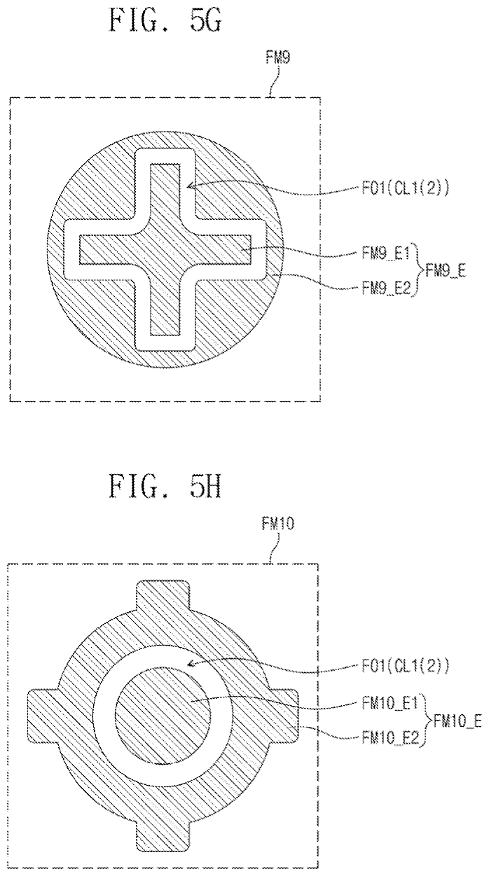

FIGS. 5A to 5H illustrate plan views showing shapes of mark exposure portions in fiducial marks according to some embodiments of the disclosure.

Referring to FIG. 5A, a third fiducial mark FM3 may include a third mark exposure portion FM3_E having a second circular segment CP2 that is positioned on a center of the third mark exposure portion FM3_E and also having second protruding segments PP2 that outwardly protrude from a circumference CP2_S of the second circular segment CP2. The number of second protruding segments PP2 may be eight, and an angle θ2 of about 45° may be provided between sidewalls PP2_S of the second protruding segments PP2. Other configurations may be the same as or similar to those discussed above.

Referring to FIG. 5B, a fourth fiducial mark FM4 may include a fourth mark exposure portion FM4_E having a third circular segment CP3 that is positioned on a center of the fourth mark exposure portion FM4_E and also having third protruding segments PP3 that outwardly protrude from a circumference CP3_S of the third circular segment CP3. The number of protruding segments PP3 may be four, and an angle θ1 of about 90° may be provided between sidewalls PP3_S of the third protruding segments PP3. The sidewalls PP3_S may each have a protruding length relatively less than that shown in FIG. 3A.

Referring to FIG. 5C, when viewed in plan, a fifth fiducial mark FM5 may include a fifth mark exposure portion FM5_E having a cavity FO that is positioned on a center of the fifth mark exposure portion FM5_E. The cavity FO may be circular.

Referring to FIG. 5D, when viewed in plan, a sixth fiducial mark FM6 may include a sixth mark exposure portion FM6_E having cavities FO that are spaced apart from each other. The cavities FO may have the same shape, and four cavities FO may be provided to have radial symmetry.

Referring to FIG. 5E, when viewed in plan, a seventh fiducial mark FM7 may include a seventh mark exposure portion FM7_E having first and second cavities FO1 and FO2 that are spaced apart from each other. The first cavity FO1 may correspond to a first-second protection layer CL1(2). The second cavity FO2 may correspond to a first-third protection layer CL1(3).

The first and second cavities FO1 and FO2 may each have an annular shape. The seventh mark exposure portion FM7_E may include a seventh-first mark exposure portion FM7_E1 at an outermost position, a seventh-second mark exposure portion FM7_E2 surrounded by the first cavity FO1, and a seventh-third mark exposure portion FM7_E3 surrounded by the second cavity FO2, which seventh-first, seventh-second, and seventh-third mark exposure portions FM7_E1, FM7_E2, and FM7_E3 are disposed in sequence in an inward direction. The seventh-second mark exposure portion FM7_E2 may have an annular shape. The seventh-third mark exposure portion FM7_E3 may have a circular shape.

Referring to FIG. 5F, when viewed in plan, an eighth fiducial mark FM8 may include an eighth mark exposure portion FM8_E having a first cavity FO1. The eighth mark exposure portion FM8_E may include an eighth-first mark exposure portion FM8_E1 having a circular circumference and an eighth-second mark exposure portion FM8_E2 surrounded by the first cavity FO1, which eighth-first and eighth-second exposure portions FM8_E1 and FM8_E2 are disposed in sequence in an inward direction. The eighth-second mark exposure portion FM8_E2 may have an annular shape.

Referring to FIG. 5G, when viewed in plan, a ninth fiducial mark FM9 may include a ninth mark exposure portion FM9_E having a first cavity FO1. The ninth mark exposure portion FM9_E may include a ninth-first mark exposure portion FM9_E1 surrounded by the first cavity FO1 and a ninth-second mark exposure portion FM9_E2 having a circular circumference, which ninth-second and ninth-first exposure portions FM9_E2 and FM9_E1 are disposed in sequence in an inward direction. The ninth-second mark exposure portion FM9_E2 may have a circular shape.

Referring to FIG. 5H, when viewed in plan, a tenth fiducial mark FM10 may include a tenth mark exposure portion FM10_E having a first cavity FO1. The tenth mark exposure portion FM10_E may include a tenth-first mark exposure portion FM10_E1 surrounded by the first cavity FO1 and a tenth-second mark exposure portion FM10_E2, which tenth-second and tenth-first exposure portions FM10_E2 and FM10_E1 are disposed in sequence in an inward direction. The tenth-second mark exposure portion FM10_E2 may have a circular shape. The tenth-first mark exposure portion FM10_E1 may have a circumference similar to that of the fourth mark exposure portion FM4_E depicted in FIG. 5B.

The mark exposure portions of fiducial marks may have their shapes that are various as discussed above, and the shapes of the mark exposure portions may be combined with each other.

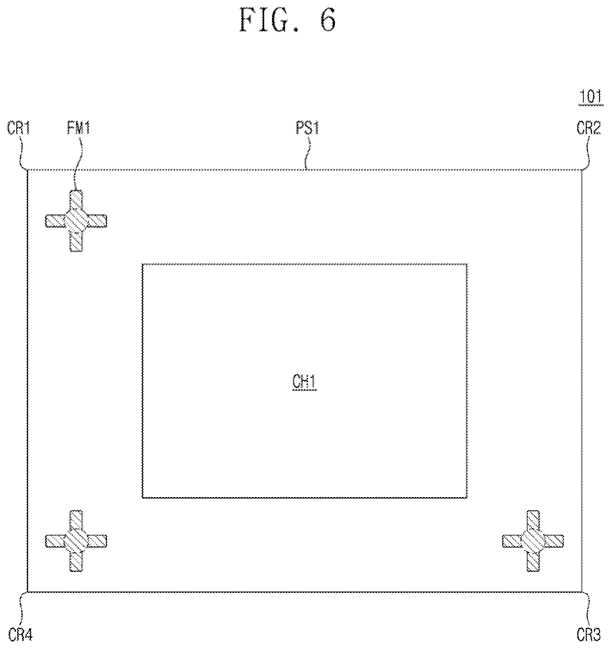

FIGS. 6 to 10 illustrate plan views showing a semiconductor package according to some embodiments of the disclosure.

Referring to FIG. 6, a semiconductor package 101 according to an embodiment may include three first fiducial marks FM1, which first fiducial marks FM1 may be correspondingly disposed adjacent to first, third, and fourth corners CR1, CR3, and CR4.

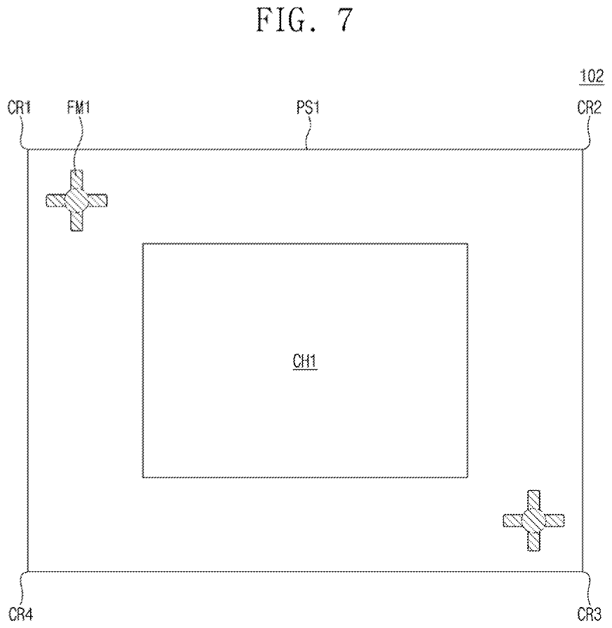

Referring to FIG. 7, a semiconductor package 102 according to an embodiment may include two first fiducial marks FM1, which first fiducial marks FM1 may be correspondingly disposed adjacent to first and third corners CR1 and CR3.

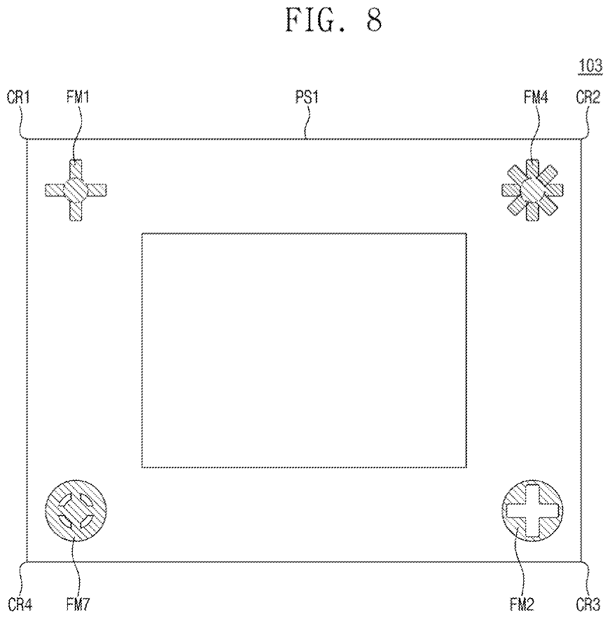

Referring to FIG. 8, a semiconductor package 103 according to an embodiment may include fiducial marks which are each adjacent to respective four corners CR1 to CR4 and whose shapes are different from each other. For example, the first fiducial mark FM1 may be disposed on the first corner CR1, the fourth fiducial mark FM4 may be disposed on the second corner CR2, the second fiducial mark FM2 may be disposed on the third corner CR3, and the seventh fiducial mark FM7 may be disposed on the fourth corner CR4. A plurality of mark exposure portions or fiducial marks may be disposed having different shapes as discussed above, and thus it may be possible to more accurately determine positions of four sides of the first substrate PS1.

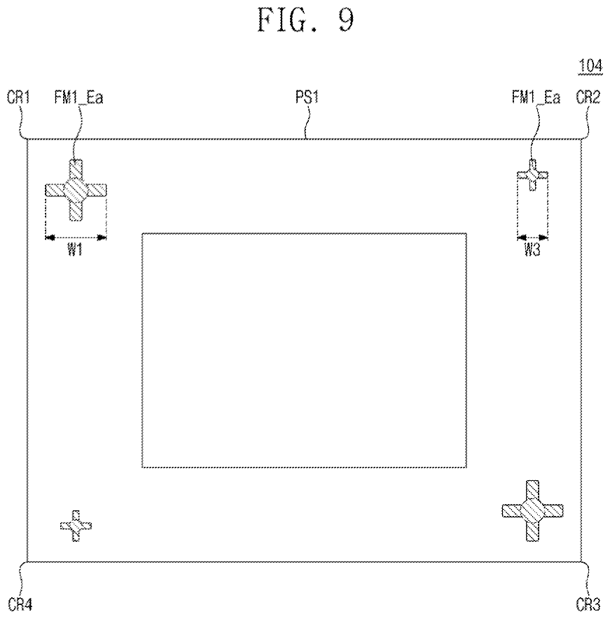

Referring to FIG. 9, a semiconductor package 104 according to an embodiment may include fiducial marks which are each adjacent to respective four corners CR1 to CR4, which fiducial marks have the same shape and different sizes from each other. For example, the first fiducial mark FM1 may be disposed on each of the four corners CR1 to CR4. The first fiducial marks FM1 adjacent to the first and third corners CR1 and CR3 may have their first mark exposure portions FM1_E each of which has a first width W1, and the first fiducial marks FM1 adjacent to the second and fourth corners CR2 and CR4 may have their first mark exposure portions FM1_E each of which has a third width W3. The third width W3 may be different from, and for example less than, the first width W1.

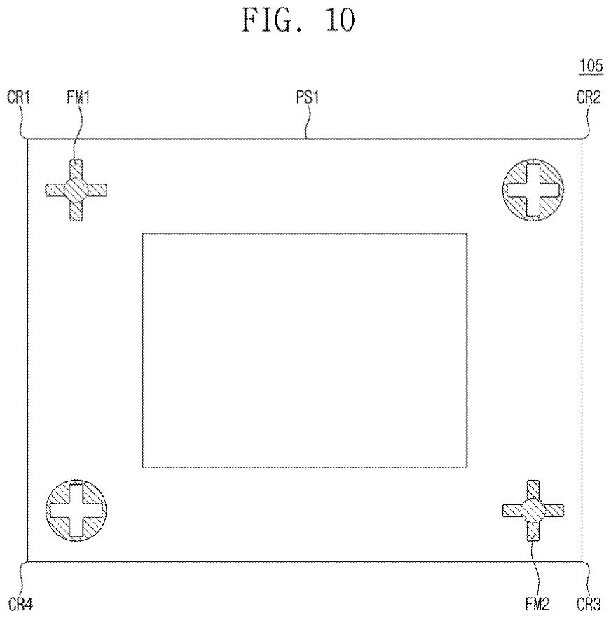

Referring to FIG. 10, a semiconductor package 105 according to an embodiment may be configured such that the first fiducial marks FM1 are adjacent to the first and third corners CR1 and CR3, and that the second fiducial marks FM2 are adjacent to the second and fourth corners CR2 and CR4.

A plurality of fiducial marks may be disposed in various ways as discussed above and may be combined with each other.

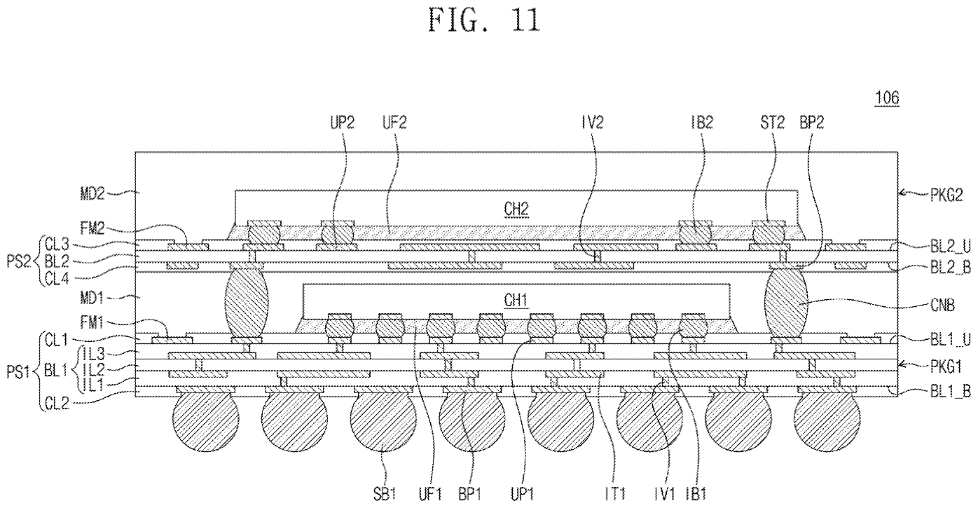

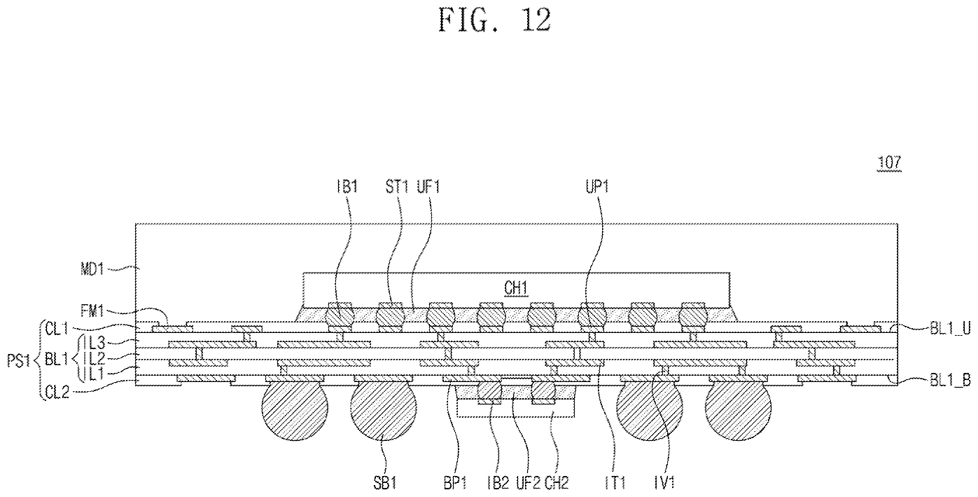

FIGS. 11 and 12 illustrate cross-sectional views showing a semiconductor package according to some embodiments of the disclosure.

Referring to FIG. 11, a semiconductor package 106 according to an embodiment may have a package-on-package structure in which a second sub-semiconductor package PKG2 is mounted on a first sub-semiconductor package PKG1. The first sub-semiconductor package PKG1 may have the same structure as that of the semiconductor package 100 depicted in FIG. 2A. The second sub-semiconductor package PKG2 may include a second substrate PS2, a second semiconductor device CH2 mounted on the second substrate PS2, and a second mold layer MD2 that covers the second semiconductor device CH2.

Although a single second semiconductor device CH2 is disclosed in the present embodiment, a plurality of second semiconductor chips CH2 may be provided laterally spaced apart from each other or vertically stacked on each other in sequence. The second semiconductor apparatus CH2 may be one selected from an image sensor chip such as a complementary metal oxide semiconductor (CMOS) image sensor (CIS), a microelectromechanical system (MEMS) device chip, an application specific integrated circuit (ASIC) chip, and a memory device chip such as a flash memory, a dynamic random access memory (DRAM), a static random access memory (SRAM), an electrically erasable programmable read-only memory (EEPROM), a phase change random access memory (PRAM), a magneto-resistive random access memory (MRAM), a resistive random access memory (ReRAM), a high bandwidth memory (HBM), and a hybrid memory cubic (HMC).

The second mold layer MD2 may include a dielectric resin, such as an epoxy molding compound (EMC). The second mold layer MD2 may further include fillers, and the fillers may be dispersed in the dielectric resin.

The second substrate PS2 may be, for example, a double-sided printed circuit board. The second substrate PS2 may include a second body layer BL2, a third protection layer CL3 that covers a top surface BL2_U of the second body layer BL2, and a fourth protection layer CL4 that covers a bottom surface BL3_B of the second body layer BL2. The second body layer BL2 may include one or more of a thermosetting resin such as epoxy resin, a thermoplastic resin such as polyimide, a resin in which a thermosetting or thermoplastic resin is impregnated with a reinforcement such as glass fiber and/or inorganic filler (which impregnated resin includes a prepreg or a fire resist-4 (FR4)), and a photosensitive resin, but the disclosure is not limited thereto. The third and fourth protection layers CL3 and CL4 may each be a photo-solder resist (PSR) layer.

The second body layer BL2 may be provided on its top surface BL2_U with second upper conductive pads UP2 and second fiducial marks FM2. The second upper conductive pads UP2 and the second fiducial marks FM2 may include the same conductive material and may be located at the same level. For example, the second upper conductive pads UP2 and the second fiducial marks FM2 may include metal, such as copper, aluminum, nickel, or gold.

When viewed in plan, the second substrate PS2 may have first to fourth corners CR1 to CR4 that are disposed along a clockwise direction. Four second fiducial marks FM2 may be correspondingly disposed adjacent to the first to fourth corners CR1 to CR4.

A plurality of second lower conductive pads BP2 may be disposed on the bottom surface BL2_B of the second body layer BL2. The second lower conductive pads BP2 may include metal, such as copper, aluminum, nickel, or gold.

The second substrate PS2 may be provided therein with second vias IV2 that penetrate the second body layer BL2.

The second semiconductor device CH2 may be provided on its bottom surface with a plurality of second chip terminals ST2. A plurality of second internal connection members IB2 may be interposed between the second chip terminals ST2 and the second upper conductive pads UP2, thereby connecting the second chip terminals ST2 to the second upper conductive pads UP2. The second internal connection members IB2 may each include at least one selected from solder balls, conductive bumps, and conductive pillars. The solder ball may include Sn or SnAg. The conductive bump or the conductive pillar may include copper.

A second under-fill layer UF2 may be interposed between the second semiconductor device CH2 and the second substrate PS2. The second under-fill layer UF2 may include a thermo-curable resin or a photo-curable resin. In addition, the second under-fill layer UF2 may further include organic fillers or inorganic fillers.

The first mold layer MD1 may be provided therein with a package connection member CNB that connects the first sub-semiconductor package PKG1 to the second sub-semiconductor package PKG2. The package connection member CNB may be one or more of conductive bumps, conductive pillars, and solder balls.

An arrangement and shape of the second fiducial marks FM2 may be the same as or similar to that of the fiducial marks discussed in FIGS. 1, 3A to 5H, and 6 to 10.

Referring to FIG. 12, a semiconductor package 107 according to an embodiment may be configured such that a second semiconductor device CH2 is mounted on a bottom surface of the first substrate PS1 in the semiconductor package 100 depicted in FIG. 2A. The second semiconductor device CH2 may be connected through the second internal connection members IB2 to ones of the first lower conductive pads BP1. A second under-fill layer UF2 may be interposed between the second semiconductor device CH2 and the first substrate PS1. The second fiducial marks FM2 may be disposed on the bottom surface BL1_B of the first body layer BL1. An arrangement and shape of the second fiducial marks FM2 may be the same as or similar to that of the fiducial marks discussed in FIGS. 1, 3A to 5H, and 6 to 10.

A semiconductor package according to the disclosure may include a fiducial mark whose mark exposure portion has a shape in which a circular segment is combined with angularly formed segments. Therefore, it may be easy to recognize circumferential points on a circumference of the mark exposure portion. In addition, it may be easy to accurately find a central point of the mark exposure portion. A plurality of angularly shaped protruding segments may be favorably used to identify directions. Accordingly, the semiconductor device may be mounted on an exact location, and process defects may not occur to increase a manufacturing yield.

Although some embodiments have been described in connection with the accompanying drawings, it will be understood to those skilled in the art that various changes and modifications may be made without departing from the technical spirit and essential feature of the disclosure. It will be apparent to those skilled in the art that various substitution, modifications, and changes may be thereto without departing from the scope and spirit of the disclosure. The embodiments of FIGS. 1 to 12 may be combined with each other.

1. A semiconductor package, comprising:
a substrate; and
at least one first semiconductor chip on the substrate,
wherein the substrate comprises:
a body layer that has a top surface and a bottom surface;
at least two first fiducial marks on the top surface of the body layer; and
a first protection layer on at least edges of each of the at least two first fiducial marks, the first protection layer having first openings that each expose a respective top surface of the at least two first fiducial marks,
wherein each of the at least two first fiducial marks comprises at least one first mark exposure portion that is exposed without being covered by the first protection layer,
wherein, when viewed in plan, each of the at least one first mark exposure portion comprises a first circular segment and at least four first protruding segments that outwardly protrude from the first circular segment,
wherein angles between sidewalls of adjacent ones of the at least four first protruding segments are identical to each other, and
wherein a lateral length of each of the at least four first protruding segments that outwardly protrude from the first circular segment is identical to the lateral length of each other of the at least four protruding segments.

2. The semiconductor package of claim 1, wherein the first circular segment of each of the at least one first mark exposure portion has a diameter of about 100 μm to about 200 μm, and
wherein each of the at least one first mark exposure portions has a width of about 300 μm to about 400 μm.

3. The semiconductor package of claim 1, wherein each of the angles between the sidewalls of the at least four first protruding segments is in a range of about 45° to about 90°.

4. The semiconductor package of claim 1, wherein the substrate comprises four corners, and
wherein each of the at least two first fiducial marks is adjacent to one of the four corners of the substrate.

5. The semiconductor package of claim 1, wherein at least two of the first mark exposure portions have different shapes from each other.

6. The semiconductor package of claim 1, further comprising at least one second semiconductor chip below the substrate,
wherein the substrate further comprises:
at least two second fiducial marks on the bottom surface of the body layer; and
a second protection layer on at least edges of each of the at least two second fiducial marks, the second protection layer having second openings that each expose a respective bottom surface of the second fiducial marks,
wherein each of the at least two second fiducial marks comprises at least one second mark exposure portion that is exposed without being covered by the second protection layer,
wherein, when viewed in plan, each of the at least one second mark exposure portion comprises a second circular segment and at least four second protruding segments that outwardly protrude from the second circular segment,
wherein angles between sidewalls of the at least four second protruding segments are identical with each other, and
wherein lateral lengths of the at least four second protruding segments that outwardly protrude from the second circular segment are identical with each other.

7. The semiconductor package of claim 6, wherein the second mark exposure portions have different shapes from each other.

8. The semiconductor package of claim 1, further comprising at least one second semiconductor chip below the substrate,
wherein the substrate further comprises:
at least two second fiducial marks on the bottom surface of the body layer; and
a second protection layer on at least edges of each of the at least two second fiducial marks, the second protection layer having second openings that each expose a respective bottom surface of the at least two second fiducial marks,
wherein each of the at least two second fiducial marks comprises at least one second mark exposure portion that is exposed without being covered by the second protection layer,
wherein, when viewed in plan, each of the at least one second mark exposure portion comprises a second circular segment and at least one cavity inside the second circular segment, and
wherein each of the at least one cavity has a radially symmetric shape.

9. The semiconductor package of claim 1, wherein the first mark exposure portions have the same shape as each other and different sizes from each other.

10. A semiconductor package, comprising:
a substrate; and
at least one first semiconductor chip on the substrate,
wherein the substrate comprises:
a body layer that has a top surface and a bottom surface;
at least two first fiducial marks on the top surface of the body layer; and
a first protection layer on at least edges of each of the at least two first fiducial marks, the first protection layer having first openings that each expose a respective top surface of the at least two first fiducial marks,
wherein each of the at least two first fiducial marks comprises at least one first mark exposure portion that is exposed without being covered by the first protection layer,
wherein, when viewed in plan, each of the at least one first mark exposure portion comprises a first circular segment and at least one cavity inside the first circular segment, and
wherein the at least one cavity of each of the at least one first mark exposure portion has a radially symmetric shape.

11. The semiconductor package of claim 10, wherein the at least one cavity of each of the first mark exposure portions has a width of about 200 μm to about 280 μm, and
wherein each of the first mark exposure portions has a width of about 300 μm to about 400 μm.

12. The semiconductor package of claim 10, wherein the substrate comprises four corners, and
wherein each of the at least two first fiducial marks is adjacent to one of the four corners of the substrate.

13. The semiconductor package of claim 10, wherein at least two of the first mark exposure portions have different shapes from each other.

14. The semiconductor package of claim 10, further comprising at least one second semiconductor chip below the substrate,
wherein the substrate further comprises:
at least two second fiducial marks on the bottom surface of the body layer; and
a second protection layer on at least edges of each of the at least two second fiducial marks, the second protection layer having second openings that each expose a respective bottom surface of the at least two second fiducial marks,
wherein each of the at least two second fiducial marks comprises at least one second mark exposure portion that is exposed without being covered by the second protection layer,
wherein, when viewed in plan, each of the at least one second mark exposure portion comprises a second circular segment and at least four second protruding segments that outwardly protrude from the second circular segment,
wherein angles between sidewalls of adjacent ones of the at least four second protruding segments are identical with each other, and
wherein a lateral length of each of the at least four second protruding segments that outwardly protrude from the second circular segment is identical to the lateral length of each other of the at least four second protruding segments.

15. The semiconductor package of claim 14, wherein the second mark exposure portions have different shapes from each other.

16. The semiconductor package of claim 10, further comprising at least one second semiconductor chip below the substrate,
wherein the substrate further comprises:
at least two second fiducial marks on the bottom surface of the body layer; and
a second protection layer on at least edges of each of the at least two second fiducial marks, the second protection layer having second openings that each expose a respective top surface of the at least two second fiducial marks,
wherein each of the at least two second fiducial marks comprises at least one second mark exposure portion that is exposed without being covered by the second protection layer,
wherein, when viewed in plan, each of the at least one second mark exposure portion comprises a second circular segment and at least one cavity inside the second circular segment, and
wherein the at least one cavity of each of the at least one second mark exposure portion has a radially symmetric shape.

17. The semiconductor package of claim 10, wherein each of the first mark exposure portions further comprises a second circular segment inside the at least one cavity or a cross segment inside the at least one cavity,
wherein the cross segment or the second circular segment of each of the first mark exposure portions has a radially symmetric shape.

18. The semiconductor package of claim 10, wherein the first mark exposure portions have the same shape as each other and different sizes from each other.

19. A semiconductor package, comprising:
a substrate;
at least one first semiconductor chip on the substrate; and
a mold layer on the first semiconductor chip and the substrate,
wherein the substrate comprises:
a body layer that has a top surface and a bottom surface;
at least two first fiducial marks on the top surface of the body layer; and
a first protection layer on at least edges of each of the at least two first fiducial marks, the first protection layer having first openings that each expose a respective top surface of the at least two first fiducial marks,
wherein each of the at least two first fiducial marks comprises at least one first mark exposure portion that is exposed without being covered by the first protection layer,
wherein, when viewed in plan, each of the at least one first mark exposure portion comprises a first circular segment and four first protruding segments that outwardly protrude from the first circular segment,
wherein each of angles between sidewalls of adjacent ones of the four first protruding segments is about 90°,
wherein a lateral length of each of the four first protruding segments that outwardly protrude from the first circular segment is identical to the lateral length of each other of the four first protruding segments,
wherein the first circular segment of each of the at least one first mark exposure portion has a diameter of about 100 μm to about 200 μm, and wherein each of the at least one first mark exposure portion has a width of about 300 μm to about 400 μm.

20. The semiconductor package of claim 19, further comprising at least one second semiconductor chip below the substrate,
wherein the substrate further comprises:
at least two second fiducial marks on the bottom surface of the body layer; and
a second protection layer on at least edges of each of the at least two second fiducial marks, the second protection layer having second openings that each expose a respective bottom surface of the at least two second fiducial marks,
wherein each of the at least two second fiducial marks comprises at least one second mark exposure portion that is exposed without being covered by the second protection layer,
wherein each of the at least one second mark exposure portion comprises a second circular segment and four second protruding segments that outwardly protrude from the second circular segment,
wherein each of angles between sidewalls of adjacent ones of the four second protruding segments is about 90°,
wherein a lateral length of each of the four second protruding segments that outwardly protrude from the second circular segment is identical to the lateral length of each other of the at least four protruding segments,
wherein the second circular segment of each of the at least one second mark exposure portion has a diameter of about 100 μm to about 200 μm, and
wherein each of the at least one second mark exposure portion has a width of about 300 μm to about 400 μm.

21. (canceled)

22. (canceled)
